(19) United States
(12) Patent Application Publication
(10) Pub. No.: US 2023/0075269 A1
(43) Pub. Date: Mar. 9, 2023

(54) DISPLAY APPARATUS

(71) Applicant: KORTEK CORPORATION, Incheon (KR)

(72) Inventor: Chagyun JEONG, Yongin-si (KR)

(21) Appl. No.: 17/560,615

(22) Filed: Dec. 23, 2021

(30) Foreign Application Priority Data
Sep. 6, 2021 (KR) 10-2021-0118555

(51) Int. Cl. G02F 1/13357; G02F 1/1333; H01L 27/15; H05B 45/32

(52) U.S. Cl. CPC G02F 1/133603; G02F 1/13338; H01L 27/156; H05B 45/32

(57) ABSTRACT

Provided is a display apparatus having an LED module composed of a plurality of LED grids and mounted on a display panel; an LED driver module; a touch sensor mounted on the display panel; a control module configured to control an operation of the LED module; and a drawing device, assigned an identifier which indicates a unique color, and configured to grasp the grid coordinates of the LED grids corresponding to contact points with the display panel through light emitted from the LED module, wherein the control module receives the identifier assigned to the drawing device and the grasped grid coordinates from the drawing device, grasps position coordinates of the contact points through the touch sensor, specifies the identifier based on a comparison result between the received grid coordinates and the grasped position coordinates, and then displays a unique color at the contact point of the position coordinates.

### CROSS-REFERENCE TO RELATED APPLICATION

This application claims priority to Korean Patent Application No. 10-2021-0118555, filed on Sep. 6, 2021, the contents of which are hereby incorporated by reference.

### FIELD OF TECHNOLOGY

The following relates to a display apparatus applicable to an electronic board system (e.g., Interactive White Board(IWB)).

### BACKGROUND

Recently, the display field has rapidly developed in accordance with the information age, and in response to this, flat panel display devices (FPD) such as a liquid crystal display (LCD), a plasma display panel (PDP), an electro luminescence display (ELD), a field emission display (FED), and the like having advantages of a thin thickness, a light weight, and low power consumption have been introduced, are rapidly replacing a conventional cathode ray tube (CRT), and are in the spotlight.

Among the above, the liquid crystal display is excellent for displaying moving images and has a high contrast ratio, and thus is most actively used in fields of a notebook computer, a monitor, a TV, and the like, and this liquid crystal display is an element not having a self-luminous element and thus requires a separate light source. Accordingly, a backlight unit (BLU) having a lamp is provided on a rear surface to emit light toward a front surface of a liquid crystal panel, and an image of identifiable luminance is realized only through this. A cold cathode fluorescent lamp, an external electrode fluorescent lamp, a light emitting diode, and the like are used as light sources of the backlight unit. Among the above, specifically, the light emitting diode (LED) has features such as a small size, low power consumption, high reliability, and the like and thus is widely used as a light source for display.

A display apparatus such as the liquid crystal display is also used as an electronic board system, and generally, the electronic board system operates to display an image (for example, a line image) on a track formed when a drawing device touches a display panel. In order to support a color of an image to be displayed, an infrared (IR) sensor method in which a color defined according to a thickness of the nib of the drawing device is displayed, or an electromagnetic resonance (EMR) method in which a specific electromagnetic wave frequency generated by the drawing device is recognized through a sensor in the display panel and a color corresponding thereto is displayed is applied. In either the IR sensor method or the EMR method, position coordinates which come into contact with the drawing device are acquired through the touch sensor mounted on the display panel, and the electronic board system operates in a method of displaying the image at the position coordinates.

In the electronic board system which supports the color, in the case of the above-described IR sensor method, since there is a disadvantage in that the thickness of the nib is fixed to a specific color, there is a limitation in diversity of colors which can be implemented, and in the case of the EMR method, since a large amount of wires for recognizing a specific frequency are required in the panel of the electronic board system, there are accompanying problems such as difficulty in manufacturing and an increase in costs.

### SUMMARY

An aspect relates to a display apparatus capable of solving various problems caused by implementation methods (that is, an infrared (IR) sensor method, an electromagnetic resonance (EMR) method, and the like) in a conventional electronic board system, that is, problems such as a limitation of color support, difficulty in a manufacturing process, and an increase in costs.

According to an aspect, there is provided a display apparatus including: a light emitting diode (LED) module composed of a plurality of LED grids and mounted on a display panel, wherein each LED grid includes one or more LED; an LED driver module configured to drive the plurality of LED grids; a touch sensor mounted on the display panel; a control module configured to apply an LED driving signal in which grid coordinates are reflected to the LED driver module to control an operation of the LED module; and a drawing device configured to come into contact with the display panel, assigned an identifier which indicates a unique color, and configured to grasp the grid coordinates of the LED grids corresponding to contact points with the display panel through light emitted from the LED module, wherein the control module receives the identifier assigned to the drawing device and the grasped grid coordinates from the drawing device, grasps position coordinates of the contact points through the touch sensor, specifies the identifier based on a comparison result between the received grid coordinates and the grasped position coordinates, and then displays a unique color corresponding to the specified identifier at the contact point of the position coordinates.

In embodiments of the present disclosure, a data communication link between the control module and the touch sensor and a communication link between the control module and the drawing device may be distinguished from each other.

In embodiments of the present disclosure, the control module may modulate the grid coordinates to the LED driving signal and apply the LED driving signal to the LED driver module so that the grid coordinates may be respectively assigned to the plurality of LED grids.

In embodiments of the present disclosure, the control module may modulate the grid coordinates to the LED driving signal using first and second pulses having the same duty ratio and corresponding to mutually inverted patterns.

In embodiments of the present disclosure, the grid coordinates may correspond to two-dimensional coordinates, and the control module may modulate a first axis coordinate of the grid coordinates to the LED driving signal corresponding to first to Kth periods, and may modulate a second axis coordinate of the grid coordinates to the LED driving signal corresponding to (K+1)th to 2Kth periods (K is a natural number greater than or equal to 2).

In embodiments of the present disclosure, the drawing device may grasp the grid coordinates of the LED grids corresponding to the contact points with the display panel through demodulation of the light emitted from the LED module.

In embodiments of the present disclosure, a plurality of drawing devices may be provided as first and second drawing devices respectively assigned first and second identifiers which indicate different unique colors.

In embodiments of the present disclosure, the control module may display a unique color corresponding to each identifier at each contact point corresponding to each pair of position coordinates using a minimum distance reference between the grid coordinates and the position coordinates in the case in which first and second position coordinates of first and second contact points are acquired by the touch sensor, as the case in which the first and second drawing devices come into contact with the first and second contact points on the display panel and thus the first and second grid coordinates are grasped.

In embodiments of the present disclosure, the control module may grasp the first grid coordinates having a minimum distance from the first position coordinates among the first and second grid coordinates according to the minimum distance reference, and may grasp the second grid coordinates having a minimum distance from the second position coordinates among the first and second grid coordinates according to the minimum distance reference, and then may display the unique color corresponding to the first identifier at the first contact point corresponding to the first position coordinates, and may display the unique color corresponding to the second identifier at the second contact point corresponding to the second position coordinates.

In embodiments of the present disclosure, the display apparatus may be applied to an electronic board system.

### BRIEF DESCRIPTION

Some of the embodiments will be described in detail, with reference to the following figures, wherein like designations denote like members, wherein:

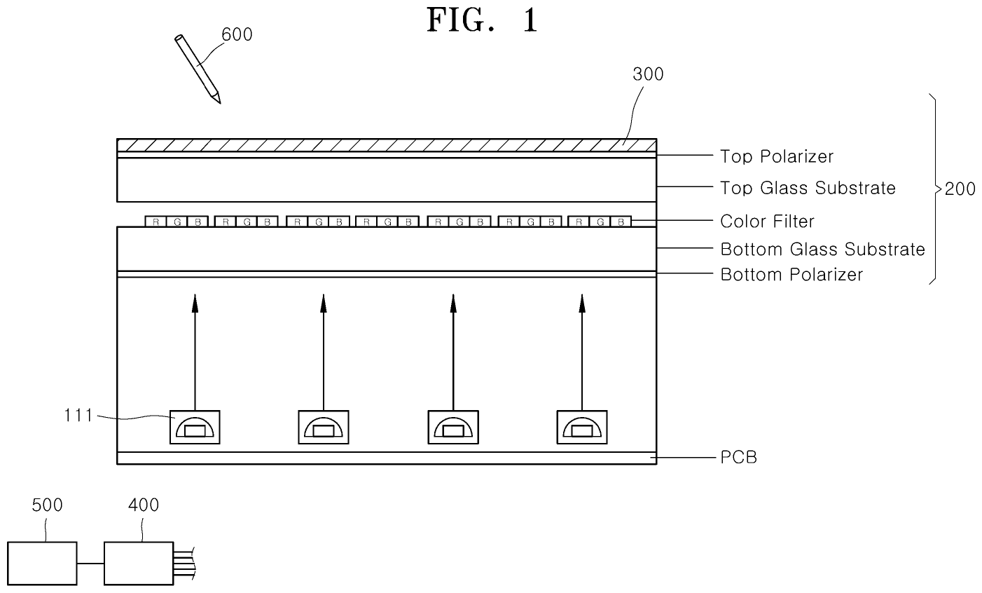

FIG. 1 is an exemplary view illustrating a structure of a display apparatus according to an embodiment;

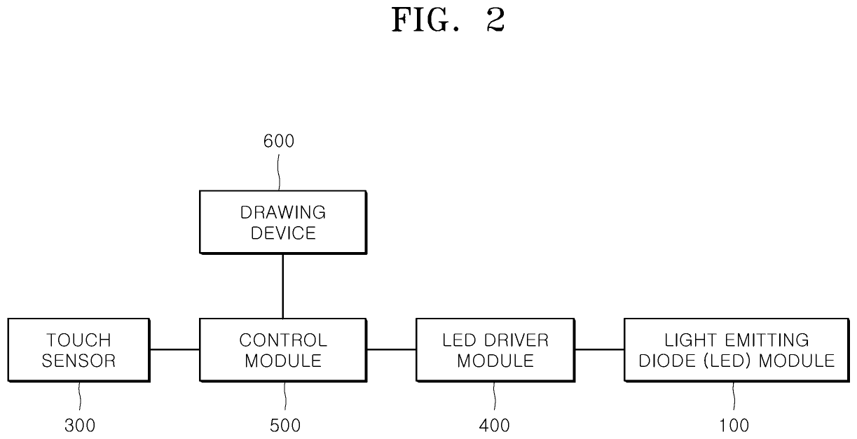

FIG. 2 is a block diagram illustrating the display apparatus according to an embodiment;

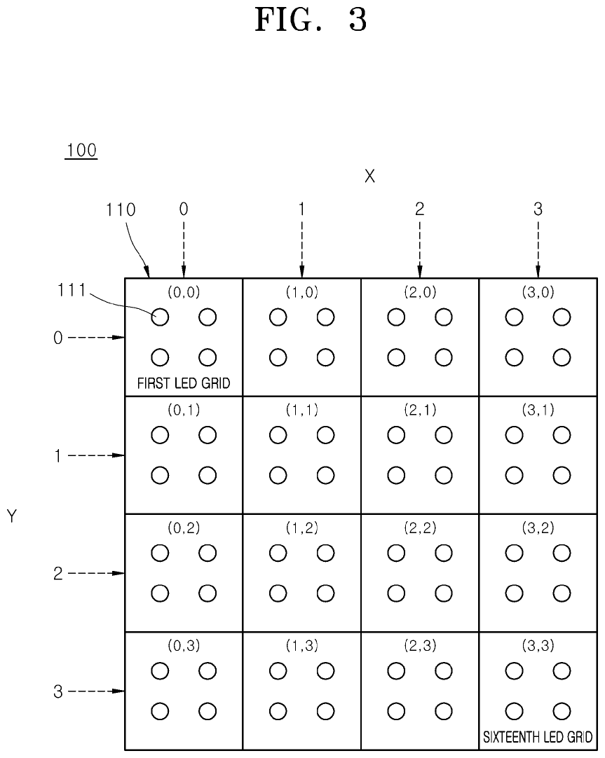

FIG. 3 is an exemplary view illustrating a plurality of light emitting diode (LED) grids constituting an LED module in the display apparatus according to an embodiment;

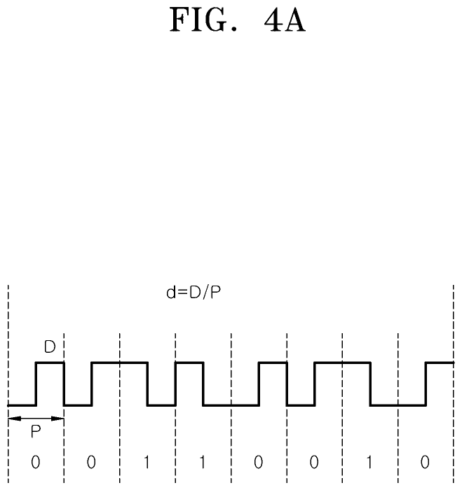

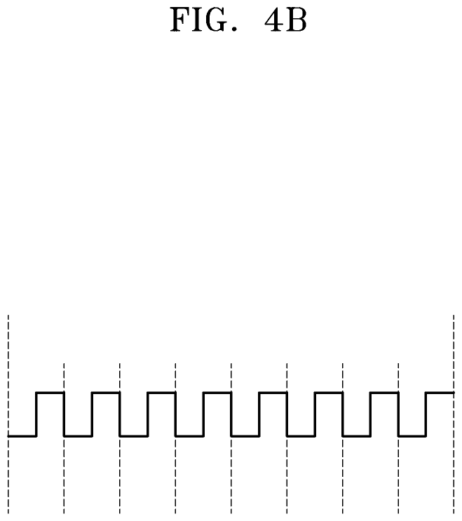

FIG. 4A is an exemplary view illustrating a method of modulating grid coordinates to an LED driving signal in the display apparatus according to an embodiment;

FIG. 4B is an exemplary view illustrating a method of modulating grid coordinates according to a conventional PWM control method; and

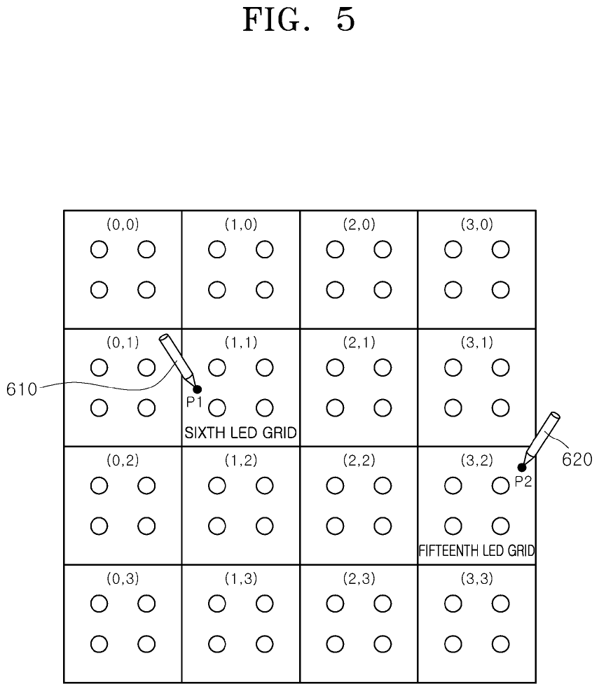

FIG. 5 is an exemplary view illustrating a process in which each unique color is displayed in an example to which two drawing devices are applied in the display apparatus according to an embodiment.

### DETAILED DESCRIPTION

Hereinafter, embodiments of a display apparatus according to embodiments of the present disclosure will be described with reference to the accompanying drawings. In this process, thicknesses of lines or sizes of the components shown in the drawings may be exaggerated for clarity and convenience of description. Further, terms to be described later are terms defined in consideration of functions in embodiments of the present disclosure, and may vary according to intentions or customs of users and operators. Accordingly, these terms should be defined based on the content throughout the specification.

FIG. 1 is an exemplary view illustrating a structure of a display apparatus according an embodiment, FIG. 2 is a block diagram illustrating the display apparatus according to an embodiment, FIG. 3 is an exemplary view illustrating a plurality of light emitting diode (LED) grids constituting an LED module in the display apparatus according to an embodiment, FIG. 4A is an exemplary view illustrating a method of modulating grid coordinates to an LED driving signal in the display apparatus according to an embodiment, and FIG. 5 is an exemplary view illustrating a process in which each unique color is displayed in an example to which two drawing devices are applied in the display apparatus according to an embodiment.

Referring to FIGS. 1 and 2, the display apparatus according to an embodiment may include an LED module 100, an optical control layer 200, a touch sensor 300, an LED driver module 400, a control module 500, and a drawing device 600.

The LED module 100 functions as a backlight unit (BLU) mounted on a display panel. As shown in FIG. 3, the LED module 100 may be composed of a plurality of LED grids 110, and each grid 110 may be configured to include one or more LEDs 111. FIG. 3 illustrates an example in which four LEDs constitute one LED grid, but an embodiment in which one LED constitutes one LED grid may be provided for more precise display control. As shown in FIG. 3, two-dimensional coordinates (that is, (x, y) coordinates) in the display panel are assigned to each LED grid, and detailed descriptions thereof will be described later.

The optical control layer 200 corresponds to a layer module formed on the LED module 100 to perform optical control of incident light from the LED module 100. As a configuration for performing the optical control of the incident light from the LED module 100, the optical control layer 200 may include polarizers (a top polarizer and a bottom polarizer), a color filter, and glass substrates (a top glass substrate and a bottom glass substrate) as shown in FIG. 1. Accordingly, the optical control layer 200 performs the optical control such as polarization and filtering for the incident light from the LED module 100 to control transmittance and a color of the light, and thus a specific image to be displayed may be displayed through the display panel.

The touch sensor 300 is formed on the LED module 100 and the optical control layer 200 to function as a sensor which senses contact (touch) of the drawing device 600, and may be implemented as various types of touch sensors such as an infrared (IR) type sensor, an ultrasonic (SAW) type sensor, a capacitive (PCAP) type sensor, and the like.

The LED driver module 400 may drive the plurality of LED grids of the LED module 100 by providing a constant current to the LED module 100 through a switch which performs a switching operation according to an LED driving signal from the control module 500 to be described later. A DC-DC converter applied as a general LED driver(LED current source) may be employed as the LED driver module 400. When a single DC-DC converter is defined as a single LED current source, in an example in which the LED module 100 includes first to Nth LED grids, the LED driver module 400 may include first to Nth LED current sources for respectively driving first to Nth LED grids (N is a natural number greater than or equal to 2).

The control module 500 may control the operation of the LED module 100 by applying the LED driving signal to the LED driver module 400 so that a specific image to be displayed may be displayed through the display panel. That is, the control module 500 may control the operation of the LED module 100 through the LED driver module 400 so that the specific image may be displayed through the optical control of the optical control layer 200 for light emitted from the LED module 100. The control module 500 may be implemented as a driver integrated circuit (IC), a microprocessor, an application process (AP), a system on chip (SoC), or a timing controller. In the control module 500, optical control information of the optical control layer 200 (for example, polarization information of the polarizers (the top polarizer and the bottom polarizer) and optical wavelength information filtered through a color filter may be defined, and accordingly, with reference to the above-described optical control information, the LED driver module 400 and the LED module 100 may be controlled so that the specific image which becomes a current display target may be generated by the optical control layer 200 and displayed.

The drawing device 600 may function as an electronic pen configured to come into contact with the display panel. The drawing device 600 may be assigned an identifier which indicates a unique color, and may grasp the grid coordinates of the LED grids corresponding to contact points with the display panel through light emitted from the LED module 100. The drawing device 600 may include an optical sensor which senses the light emitted from the LED module 100, a controller for demodulating the optical signal sensed through the optical sensor, and a communication board for near field wireless communication (for example, Wi-Fi, Bluetooth, Zigbee) with the control module 500. Accordingly, a data communication link between the control module and the touch sensor and a communication link between the control module and the drawing device are distinguished from each other (that is, the control module communicates with the touch sensor and the drawing device through different communication channels). Detailed descriptions of an operation of the drawing device 600 will be described later.

Based on the above, hereinafter, the display apparatus of an embodiment will be specifically described focusing on operations of the control module 500, the touch sensor 300, and the drawing device 600.

In an embodiment, the control module 500 may control the operation of the LED module 100 by applying the LED driving signal in which the grid coordinates are reflected to the LED driver module 400, and specifically, may modulate the grid coordinates to the LED driving signal and apply the LED driving signal to the LED driver module 400 so that the grid coordinates may be respectively assigned to the plurality of LED grids.

As mentioned above, the grid coordinates, which are two-dimensional coordinates, are respectively assigned to the LED grids, and FIG. 3 illustrates an example in which the grid coordinates of (0, 0) to (3, 3) are respectively assigned to first to sixteenth LED grids. Accordingly, the control module 500 may modulate the grid coordinates of (0, 0) to the LED driving signal (for example, the LED driving signal applied to the first LED driver) to control an operation of the first LED grid, may modulate the grid coordinates of (0, 1) to the LED driving signal (for example, the LED driving signal applied to the second LED driver) to control an operation of the second LED grid, and may apply the same method to operation control up to the sixteenth LED grid to control an operation of the sixteenth LED grid by modulating the grid coordinates of (3, 3) to the LED driving signal (for example, the LED driving signal applied to the sixteenth LED driver).

As a specific method of modulating the grid coordinates to the LED driving signal, the control module 500 may modulate the grid coordinates to the LED driving signal using first and second pulses having the same duty ratio and corresponding to mutually inverted patterns (for this, as an example, a pulse width modulation (PWM) signal may be employed as the LED driving signal). Further, the control module 500 may modulate a first axis coordinate (x-axis coordinate) of the grid coordinates to an LED driving signal corresponding from the first to the Kth periods, and may modulate a second axis coordinate (y-axis coordinate) of the grid coordinates to an LED driving signal corresponding from the (K+1)th to the 2Kth periods (K is a natural number greater than or equal to 2, and may correspond to a variable according to system requirement). The first and second pulses are selectively reflected in one period of the LED driving signal.

FIG. 4A illustrates a modulation example when K has a value of 4 (one period is P). The first axis coordinate is modulated from the first to the fourth periods of the LED driving signal, and the second axis coordinate is modulated from the fifth to the eighth periods of the LED driving signal. The first and second pulses both have a 50% duty ratio and are defined as pulses corresponding to the mutually inverted patterns, wherein the first pulse is defined to have a binary value of 0, and the second pulse is defined to have a binary value of 1. Accordingly, the first axis coordinate is modulated from the first to the fourth periods of the LED driving signal as coordinate information of ‘0011’, the second axis coordinate is modulated form the fifth to the eighth periods of the LED driving signal as coordinate information of ‘0010’, and the modulated LED driving signal is applied to the LED driver module 400 as a signal for operation control of the fifteenth LED grid. The following Table 1 shows a modulation method of each LED control signal for operation control of the first to sixteenth LED grids in the example in FIG. 4A.

TABLE 1

| | LED driving | LED driving |
|---|---|---|
| LED grids | signal (First to | signal (Fifth to |
| (grid coordinates) | fourth periods) | eighth periods) |
| First LED grid (0, 0) | 0000 | 0000 |
| Second LED grid (0, 1) | 0000 | 0001 |
| Third LED grid (0, 2) | 0000 | 0010 |
| Fourth LED grid (0, 3) | 0000 | 0011 |
| Fifth LED grid (1, 0) | 0001 | 0000 |
| Sixth LED grid (1, 1) | 0001 | 0001 |
| Seventh LED grid (1, 2) | 0001 | 0010 |
| Eighth LED grid (1, 3) | 0001 | 0011 |
| Ninth LED grid (2, 0) | 0010 | 0000 |
| Tenth LED grid (2, 1) | 0010 | 0001 |
| Eleventh LED grid (2, 2) | 0010 | 0010 |
| Twelfth LED grid (2, 3) | 0010 | 0011 |
| Thirteenth LED grid (3, 0) | 0011 | 0000 |
| Fourteenth LED grid (3, 1) | 0011 | 0001 |
| Fifteenth LED grid (3, 2) | 0011 | 0010 |
| Sixteenth LED grid (3, 3) | 0011 | 0011 |

Since the above modulation method has the same duty ratio as that in FIG. 4B, which is a conventional PWM control method, it is guaranteed that the coordinate information may be modulated to the LED driving signal without changing the luminance of the light emitted from the LED module 100.

The drawing device 600 may grasp the grid coordinates of the LED grids corresponding to the contact points with the display panel through demodulation of the light emitted from the LED module 100. For example, when the drawing device 600 touches a region of the fifteenth LED grid and receives light emitted from the fifteenth LED grid, since the fifteenth LED grid is controlled according to the LED driving signals modulated as ‘0011’ and ‘0010’, the drawing device 600 may sense and demodulate a change in brightness of the light emitted from the fifteenth LED grid through the optical sensor to grasp (3, 2), which are the grid coordinates of the fifteenth LED grid.

Hereinafter, wherein the control module 500 may receive the identifier assigned to the drawing device 600 and the grid coordinates grasped like the above from the drawing device 600, may grasp position coordinates of the contact points with the drawing device 600 and the display panel through the touch sensor 300, may specify the identifier of the drawing device 600 based on a comparison result between the grid coordinates received from the drawing device 600 and the position coordinates grasped through the touch sensor 300, and then may display a unique color corresponding to the specified identifier at the contact point of the position coordinate (display of the unique color is subject to control over a user interface (UI) as usual).

In an example in which one drawing device 600 assigned an identifier ‘1’ which indicates the unique color is provided, when it is assumed that grid coordinates received from the drawing device 600 are (1, 1), and position coordinates grasped by the touch sensor 300 are (1.5, 1.3), the control module 500 may compare the grid coordinates (1, 1) and the position coordinates (1.5, 1.3) to specify the identifier ‘1’ received from the drawing device 600 together with the coordinates (1, 1), and display a unique color corresponding to the specified identifier ‘1’ at a contact point of the position coordinates (1.5, 1.3) when a distance between the coordinates (1, 1) and the position coordinates (1.5, 1.3) is smaller than or equal to a preset reference value.

Meanwhile, in embodiments of the present embodiment, a plurality of drawing devices 600 may be provided as first and second drawing devices 610 and 620 respectively assigned first and second identifiers which indicate different unique colors.

The control module 500 may display the unique color corresponding to each identifier at each contact point corresponding to each pair of position coordinates using a minimum distance reference between the grid coordinates and the position coordinates in the case in which first and second position coordinates of first and second contact points are acquired by the touch sensor 300, as the case in which the first and second drawing devices 610 and 620 come into contact with the first and second contact points on the display panel and thus the first and second grid coordinates are grasped.

Specifically, the control module 500 may grasp the first grid coordinates having a minimum distance from the first position coordinates among the first and second grid coordinates according to the minimum distance reference and may grasp the second grid coordinates having a minimum distance from the second position coordinates among the first and second grid coordinates according to the minimum distance reference, and then may display a unique color corresponding to a first identifier at the first contact point corresponding to the first position coordinates and may display a unique color corresponding to a second identifier at the second contact point corresponding to the second position coordinates.

The above will be described as a specific example with reference to FIG. 5, and a state in which the first identifier ‘1’ (for example, black) is assigned to the first drawing device 610 and the first drawing device 610 comes into contact with a first contact point P1 of the sixth LED grid (the grid coordinates: (1, 1)) and a state which the second identifier ‘2’ (for example, red) is assigned to the second drawing device 620 and the second drawing device 620 comes into contact with a second contact point P2 of the fifteenth LED grid (the grid coordinates: (3, 2)) are assumed. Further, a state in which coordinates (1.2, 1.5) are acquired as the first position coordinates of the first contact point P1 by the touch sensor 300, and coordinates (3.7, 2.2) are acquired as the second position coordinates of the second contact point P2 is assumed. Accordingly, the control module 500 receives data of (‘ 1’, (1, 1)) from the first drawing device 610, receives data of (‘2’, (3, 2)) from the second drawing device 620, and receives data of (1.2, 1.5), (3.7, 2.2) as the first and second position coordinates from the touch sensor 300.

As mentioned above, since the control module 500 communicates with the touch sensor 300 and the drawing device 600 through different communication channels, a reference for determining whether to display black according to the first identifier or red according to the second identifier at the first position coordinates is required from the standpoint of the control module 500, and like the above, a reference for determining whether to display black according to the first identifier or red according to the second identifier at the second position coordinates is required. As the above reference, in an embodiment, the minimum distance reference is applied.

Accordingly, the control module 500 compares the first grid coordinates (1, 1) and the second grid coordinates (3, 2) with the first position coordinates (1.2, 1.5) to determine distances between the coordinates. Among the first and second grid coordinates, since the coordinates having the minimum distance from the first position coordinate are the first grid coordinates, the control module 500 displays black corresponding to the first identifier received together with the first grid coordinates at the first contact point P1 corresponding to the first position coordinates. Like the above, the control module 500 compares the first grid coordinates (1, 1) and the second grid coordinates (3, 2) with the second position coordinates (3.7, 2.2) to determine distances between the coordinates. Among the first and second grid coordinates, since the coordinates having the minimum distance from the second position coordinates are the second grid coordinates, the control module 500 displays red corresponding to the second identifier received together with the second grid coordinates at the second contact point P2 corresponding to the second position coordinates. Through the above mechanism, even when the plurality of drawing devices are touched on the display panel, the specific colors may be displayed at accurate positions.

Like the above, in an embodiment, since the LED module such as a backlight unit of the display panel is composed of a plurality of LED grids, the grid coordinates of the LED grids are modulated to the LED driving signal, and the light from the LED module is demodulated through the drawing device to grasp the grid coordinates of the LED grids corresponding to the contact points of the display panel and then the specific color is displayed at the above-described contact point, a problem of design complexity of the drawing device depending on the type of touch sensor may be removed and design easiness of the drawing device may be secured. Further, according to one aspect of embodiments of the present disclosure, since the identifier which indicates the unique color to the drawing device is pre-assigned and then the unique color corresponding to the assigned identifier is displayed, ease and expandability of color support may be achieved compared to the conventional IR sensor method or EMR method, and even when the plurality of drawing devices are touched, the specific color may be displayed at the accurate position.

According to one aspect of embodiments of the present disclosure, since a light emitting diode (LED) module such as a backlight unit of a display panel is composed of a plurality of LED grids, grid coordinates of the LED grids are modulated to an LED driving signal, and light from an LED module is demodulated through a drawing device to grasp the grid coordinates of the LED grids corresponding to contact points of the display panel and then a specific color is displayed at the above-described contact point, a problem of design complexity of a drawing device depending on the type of touch sensor can be removed and design easiness of the drawing device can be secured.

Further, according to one aspect of embodiments of the present disclosure, since an identifier which indicates a unique color to the drawing device is pre-assigned and then the unique color corresponding to the assigned identifier is displayed, ease and expandability of color support can be achieved compared to a conventional infrared (IR) sensor method or electromagnetic resonance (EMR) method, and even when a plurality of drawing devices are touched, the specific color can be displayed at an accurate position.

Although the present invention has been disclosed in the form of preferred embodiments and variations thereon, it will be understood that numerous additional modifications and variations could be made thereto without departing from the scope of the invention.

For the sake of clarity, it is to be understood that the use of “a” or “an” throughout this application does not exclude a plurality, and “comprising” does not exclude other steps or elements. The mention of a “unit” or a “module” does not preclude the use of more than one unit or module.

What is claimed is:

1. A display apparatus comprising:
a light emitting diode (LED) module composed of a plurality of LED grids and mounted on a display panel, wherein each LED grid includes one or more LEDs;
an LED driver module configured to drive the plurality of LED grids;
a touch sensor mounted on the display panel;
a control module configured to apply an LED driving signal in which grid coordinates are reflected to the LED driver module to control an operation of the LED module; and
a drawing device configured to come into contact with the display panel, assigned an identifier which indicates a unique color, and configured to grasp the grid coordinates of the LED grids corresponding to contact points with the display panel through light emitted from the LED module,
wherein the control module receives the identifier assigned to the drawing device and the grasped grid coordinates from the drawing device, grasps position coordinates of the contact points through the touch sensor, specifies the identifier based on a comparison result between the received grid coordinates and the grasped position coordinates, and then displays a unique color corresponding to the specified identifier at the contact point of the position coordinates.

2. The display apparatus of claim 1, wherein a data communication link between the control module and the touch sensor and a communication link between the control module and the drawing device are distinguished from each other.

3. The display apparatus of claim 1, wherein the control module modulates the grid coordinates to the LED driving signal and applies the LED driving signal to the LED driver module so that the grid coordinates are respectively assigned to the plurality of LED grids.

4. The display apparatus of claim 3, wherein the control module modulates the grid coordinates to the LED driving signal using first and second pulses having the same duty ratio and corresponding to mutually inverted patterns.

5. The display apparatus of claim 4, wherein:
the grid coordinates correspond to two-dimensional coordinates; and
the control module modulates a first axis coordinate of the grid coordinates to the LED driving signal corresponding from the first to the Kth periods, and modulates a second axis coordinate of the grid coordinates to the LED driving signal corresponding from the (K+1)th to the 2Kth periods (K is a natural number greater than or equal to 2).

6. The display apparatus of claim 3, wherein the drawing device grasps the grid coordinates of the LED grids corresponding to the contact points with the display panel through demodulation of the light emitted from the LED module.

7. The display apparatus of claim 1, wherein a plurality of drawing devices are provided as first and second drawing devices respectively assigned first and second identifiers which indicate different unique colors.

8. The display apparatus of claim 7, wherein the control module displays a unique color corresponding to each identifier at each contact point corresponding to each pair of position coordinates using a minimum distance reference between the grid coordinates and the position coordinates when first and second position coordinates of first and second contact points are acquired by the touch sensor, as the case in which the first and second drawing devices come into contact with the first and second contact points on the display panel and thus the first and second grid coordinates are grasped.

9. The display apparatus of claim 8, wherein the control module grasps the first grid coordinates having a minimum distance from the first position coordinates among the first and second grid coordinates according to the minimum distance reference, and grasps the second grid coordinates having a minimum distance from the second position coordinates among the first and second grid coordinates according to the minimum distance reference, and then displays the unique color corresponding to the first identifier at the first contact point corresponding to the first position coordinates and displays the unique color corresponding to the second identifier at the second contact point corresponding to the second position coordinates.

10. The display apparatus of claim 1, wherein the display apparatus is applied to an electronic board system.
